(19) United States
(12) Patent Application Publication
(10) Pub. No.: US 2002/0038690 A1
(43) Pub. Date: Apr. 4, 2002

(54) Surface structure for vacuum treatment apparatus

(75) Inventors: Michio Minato, Chiba-ken (JP); Hideo Iwamoto, Chiba-ken (JP)

Correspondence Address: ARENT FOX KINTNER PLOTKIN & KAHN, PLLC, Suite 600, 1050 Connecticut Avenue, Washington, DC, 20036-5339, US

(73) Assignee: Shinkuu Yakin Kabushiki Kaisha (also trading as Vacuum Metallurgical Co., Ltd.)

(21) Appl. No.: 09/966,077

(22) Filed: Oct. 1, 2001

(30) Foreign Application Priority Data
Sep. 29, 2000 (JP) 297902/2000

(51) Int. Cl. C23F 1/02; C23C 16/00

(52) U.S. Cl. 156/345; 118/715; 204/298.02

(57) ABSTRACT

A member made of glass, ceramics, a metal or the like which is used in vacuum in a vacuum treatment chamber is located in an inert gas atmosphere and an arc spray film of a metal is formed on a surface of the member by arc spraying the metal using an inert gas as a blowing gas. Argon gas is used as the inert gas and a member for a vacuum apparatus such a vacuum vessel is considered as the member made of glass, ceramics, a metal or the like.

### BACKGROUND OF THE INVENTION

1. Field of the Invention

The present invention relates to a surface structure of a vacuum component or a vacuum vessel which is located in a vacuum treatment apparatus, such as sputtering and CVD.

2. Description of the Related Art

Conventionally, there has been a demand for reducing particle generation during a film deposition in a semiconductor equipment such as a sputtering equipment and a manufacturing equipment for a magnetic film for recording. Such particles are generated due to the fact that a film which has been deposited thickly on a surface of a vacuum component or an inner wall of a vacuum vessel except for a substrate on which a film should be formed in a film formation chamber is burst partly or the film itself is peeled off by internal stress in the film. In order to avoid this particle generation, such a process has been tried as a preparation of undulation on a surface of a vacuum component or an inner wall of a vacuum vessel, and a formation of an underground film or an intermediate film for avoiding the peeling-off of a deposited film.

As the conventional ground film formed on a vacuum component or a vacuum vessel for particle reduction, a film of a pure metal, such as aluminum, titanium, molybdenum, nickel, stainless steel and copper, or an alloy thereof formed by a spraying process is used. Also, as this spraying process, a flame spraying process or an arc spraying process is employed wherein a wire- or rod-shaped evaporation material made of a pure metal or an alloy can be used. In each process, spraying is performed in an atmosphere to form the ground film. In such an environment, the evaporated metal or alloy is easily combined with the atmospheric oxygen or nitrogen due to the heat of the evaporated metal or alloy itself, and when the metal or alloy is formed on a subject surface, the metal or alloy is oxidized or nitrided, which results in formation of an oxide film or a nitride film having high hardness.

Since fine cracks occur in such a spray film having high hardness due to the internal stress and a large amount of water is absorbed in the cracks, there is a drawback that, when an environment wherein the vacuum component or vacuum vessel having the spray film is disposed is evacuated, a pumping time is tend to be increased for removing a large amount of water which has been absorbed in the cracks.

### OBJECT AND SUMMARY OF THE INVENTION

An object of the present invention is to provide a surface structure for a vacuum treatment chamber which comprises a spray film wherein such cracks do not occur.

The present invention has achieved its object by locating a member made of glass, ceramics, a metal or the like which is used in vacuum in a vacuum treatment chamber in an inert gas atmosphere and forming an arc spray film on a surface of the member made of glass, ceramics, a metal or the like by arc spraying a metal using an inert gas as a blowing gas. From the viewpoint of ease in handling and costs, it is preferable that argon gas is used as an inert gas, and a member for a vacuum apparatus such as a vacuum vessel is considered as the member made of glass, ceramics, a metal or the like.

### BRIEF DESCRIPTION OF THE DRAWINGS

FIG. 1 is an explanatory diagram showing an embodiment of the present invention;

FIG. 2 is a graph showing a change in the outgassing rate of a surface structure of the present invention and a conventional surface structure; and

FIG. 3 is a graph showing a change in the pressure of the surface structure of the present invention and of the conventional structure.

### DETAILED DESCRIPTION OF THE PREFERRED EMBODIMENT

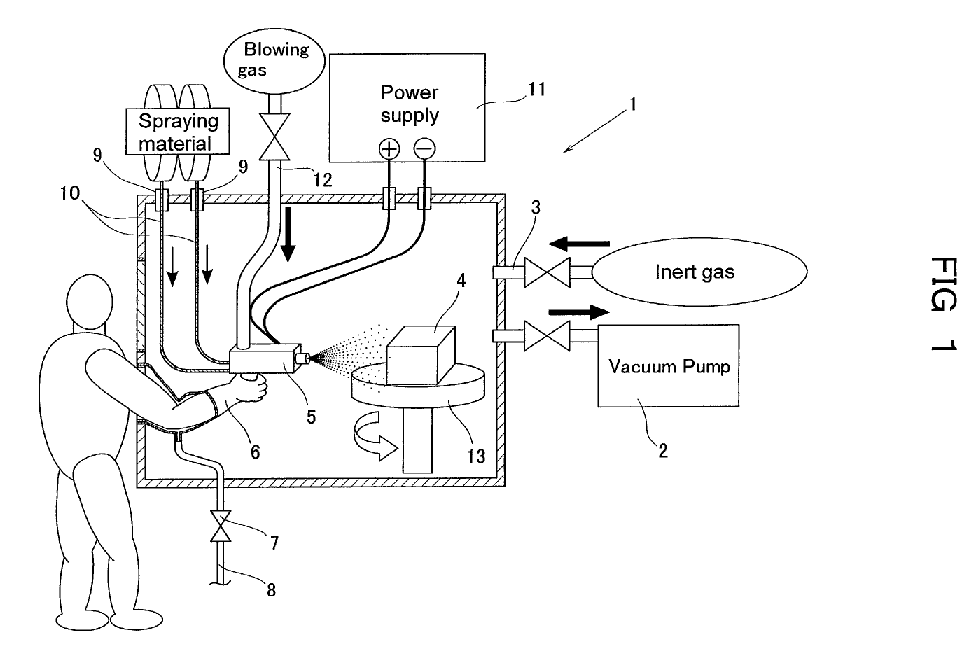

An embodiment of the present invention will be explained with reference to the drawings. FIG. 1 shows an explanatory diagram of an apparatus for obtaining a surface structure for a vacuum treatment chamber of the present invention, wherein reference numeral 1 denotes a spaying container made of stainless steel, which is exhausted to vacuum by an vacuum pump 2 and to which an inert gas such as argon is introduced by an inert gas introducing pipe 3. A member 4 made of glass, ceramics, metal or the like, which comprises a vacuum component or a vacuum vessel, and an arc gun 5 for spraying are disposed within the spray container 1 and an arc spray film is formed on a surface of the member 4.

A rubber glove 6 for manually operating the arc gun 5 is mounted to a side of the spray container 1, and a vacuum pipe 8 connected to a vacuum pump via a valve 7 is opened on a side of atmosphere. A wire-like evaporation material made of a metal or an alloy is drawn into the arc gun 5 from the outside via a vacuum seal 9, arc power is supplied to the arc gun from an arc power supply 11, and blowing gas is fed to the arc gun from a gas pipe 12 connected to an inert gas source. Reference numeral 13 is a working table with a placed member 4 which is rotated.

The spray container 1 has an inner diameter of 1.5 m and a depth of 1.5 m, for example. After the inside of the container 1 is exhausted to 10 Pa, it is filled with argon gas from the inert gas introducing pipe 3 so as to achieve a pressure of 1.1×10⁵ Pa which is slightly higher than atmospheric pressure. At the time of the exhaust, the atmospheric side of the rubber glove 6 is simultaneously exhausted through the vacuum pipe 8, thereby preventing the rubber glove from being injured. Next, after argon gas is filled in the spray container 1, when the vacuum pipe 8 is closed, the rubber glove 6 bulges outwardly so that an operator can easily grasp or handle the arc gun 5. Arc spraying can be performed on the member 4 in the argon gas atmosphere by operating the arc gun 5. In the conventional arc spraying process, compressed air is employed as a blowing gas, but in this invention, argon gas of 0.5 to 7.0 kg/mm² is employed as a blowing gas and an inert gas is used for both the blowing and the atmosphere. An metal spray film is formed on a surface of the member 4 by this arc spraying process. Since the metal spray film thus obtained is formed in the inert gas by the inert gas blowing, the coating film has reduced an oxygen or nitrogen content and has a metallic glossy which is similar to that of a pure metal. Since no crack occurs in an surface of the film and moisture in the atmosphere is not absorbed in the film, the film is suitable for a surface structure of a vacuum vessel or a vacuum component.

An arc spray film of titanium may be formed on a member 4 made of glass, ceramics, a metal or the like which is employed as a ground shield of a semiconductor sputtering device or an inner wall of a vacuum vessel, and an arc spray film of aluminum may be formed on a member 4 made of glass, ceramics, a metal or the like, which is employed as a cover ring for a magnetic film sputtering apparatus or a hard disc holder in an inline apparatus for a magnetic film sputtering.

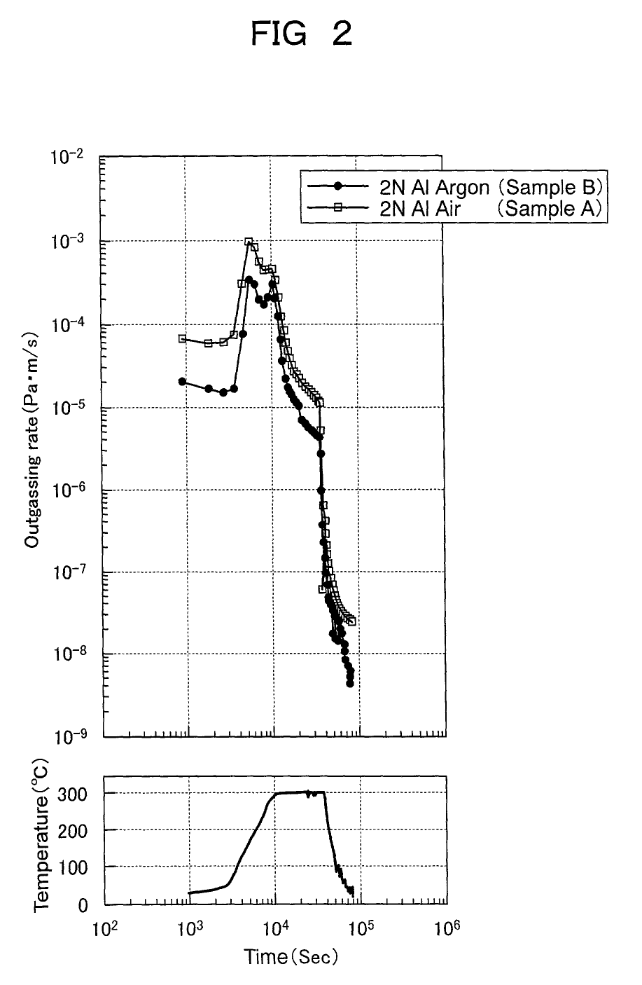

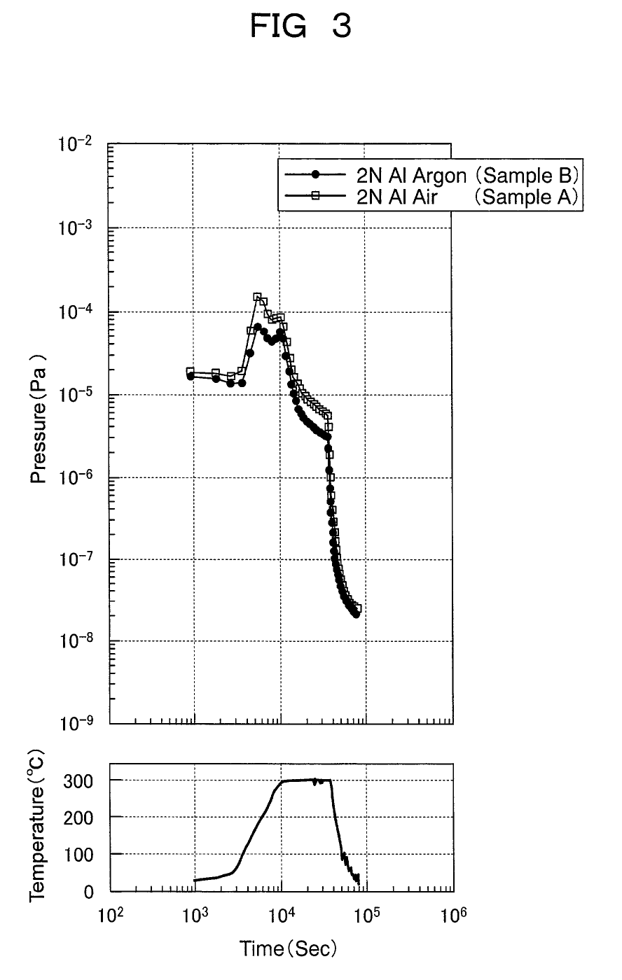

A surface structure (sample A) of a spray film formed by a conventional aluminum spraying with compressed air in the atmosphere and a surface structure (sample B) of a spray film formed by aluminum arc spraying of the present invention using an inert gas as a blowing gas in an inert gas atmosphere were respectively prepared on metal members comprising a pure titanium vacuum component. Both the metal members of the conventional surface structure and the surface structure of the present invention were located in the same vacuum chamber and the vacuum chamber was heated and evacuated. At this time, regarding the change in pressure and outgassing rate, both the metal members were compared with each other to obtain the results shown in FIG. 2. The total outgassing volume is obtained by integrating the outgassing rate with time, wherein in the conventional surface structure the total outgassing volume is 5.0 Pa·m³/m² but in the surface structure of the present invention it is 2.1 Pa·m³/m² which is half or less than the former value. Accordingly, the pumping time is reduced to half or less than the conventional surface structure. FIG. 3 shows pumping curves. In the surface structure of the present invention, the pumping time has been reduced.

As mentioned above, according to the present invention, since a member made of glass, ceramics, a metal or the like which is used in vacuum in a vacuum treatment chamber is located in an inert gas atmosphere and an arc spray film of a metal is provided on a surface of the member made of glass using an inert gas as a blowing gas, a ceramic member or a metal member, such an effect can be achieved that a spray film wherein no crack occurs can be obtained, a surface structure suitable for a vacuum treatment chamber wherein a outgassing amount is reduced and an pumping time is shortened, and the surface structure can be manufactured with ease and at a low cost.

What is claimed is:

1. A surface structure for a vacuum treatment chamber comprising an arc spray film of a metal coated on a surface of a member made of glass, ceramics, a metal or the like, wherein said arc spray film is formed by arc spraying the metal using an inert gas as a blowing gas, in an inert gas atmosphere.

2. The surface structure for a vacuum treatment chamber according to claim 1, wherein said inert gas is argon gas.

3. The surface structure for a vacuum treatment chamber according to claim 1 or 2, wherein said member is a component for a vacuum apparatus, such as a vacuum vessel and a substrate holder.

4. A surface treatment method for a vacuum treatment chamber, wherein a member made of glass, ceramics, a metal or the like which is used in said vacuum treatment chamber is located in an inert gas atmosphere and an arc spray film of a metal is formed on a surface of said member by arc spraying the metal using an inert gas for a blowing gas.
